(19) United States
(12) Patent Application Publication
(10) Pub. No.: US 2005/0285272 A1
(43) Pub. Date: Dec. 29, 2005

(54) Conductive structures in integrated circuits

(75) Inventor: Paul A. Farrar, So. Burlington, VT (US)

Correspondence Address: SCHWEGMAN, LUNDBERG, WOESSNER & KLUTH, 1600 TCF TOWER, 121 SOUTH EIGHT STREET, MINNEAPOLIS, MN, 55402, US

(73) Assignee: Micron Technology, Inc.

(21) Appl. No.: 11/216,693

(22) Filed: Aug. 31, 2005

Related U.S. Application Data
(62) Division of application No. 09/259,849, filed on Mar. 1, 1999.

(51) Int. Cl. H01L 23/48

(52) U.S. Cl. 257/758; 257/774

(57) ABSTRACT

A connective structure is formed by first depositing an insulator over a planarized surface. A trench is etched in the insulator. A barrier layer is deposited on the insulator. A seed layer is deposited on the barrier layer. The barrier layer and seed layer are selectively removed from areas of the insulator leaving an exposed seed area. A conductor is deposited on the exposed seed area. As many of these connective structures as desired may be stacked in an integrated circuit structure.

This application is a Divisional of U.S. application Ser. No. 09/259,849 filed Mar. 1, 1999, which application is incorporated herein by reference.

### FIELD OF THE INVENTION

This invention relates to integrated circuits, and more particularly, to conductive structures used in integrated circuits.

### BACKGROUND OF THE INVENTION

As the dimensions of the devices and conductors that make up an integrated circuit decrease, several problems arise. First, as the cross-sectional area of the conductors decrease, the resistivity of the conductors increase, which, as current flows in the conductors, results in an increase in the heat generated by the conductors. Second, as the dimensions of the devices decrease, the devices and conductors are packed more tightly in the integrated circuit, and the distance between the conductors decreases, which results in an increase in the capacitance between the conductors. This increase in capacitance reduces the speed at which information can be transmitted along the conductors.

The first problem, increased heating resulting from a decrease in the cross-sectional area of a conductor in an integrated circuit can cause the integrated circuit to fail. Despite advances in devices, such as heat sinks which are designed to remove heat from an integrated circuit, it is still important to reduce the heat generated internal to the integrated circuit. Fabricating the conductors in an integrated circuit from a metal, such as copper, which has a higher conductivity than the industry standard aluminum conductor, is one way to eliminate the heat generated in the conductor. Unfortunately, the use of copper as a conductor in an integrated circuit generates another problem. Copper diffuses into the materials that make up the integrated circuit, and the diffused copper alters the electrical properties of those materials.

The second problem, increased capacitance between the conductors, decreases the rate at which information can be transmitted along the conductors. One approach to solving this problem is to use an insulator having a smaller dielectric constant than the industry standard silicon dioxide, in order to decrease the capacitance between the conductors. Polymers have a smaller dielectric constant than silicon dioxide, but the use of polymers as insulators in integrated circuits creates another problem. It is well known that both gold and copper are fast diffusers in silicon, poisoning devices by degrading minority carrier lifetime. It is also known that copper especially, diffuses rapidly through silicon oxide. It is also well known that copper will react with organic acids like polyimide acid, which is used as a precursor for the formation of many polyimide films, forming CuO which degrades the resulting polymer. Therefore, a number of barrier materials have been studied to prevent the penetration of copper into oxide or the reaction of copper with polymeric acid precursors. Among the more successful are tantalum and tantalum nitride. It has also been found that if polyimide is formed not from a acid but an ester based starting material, that the reaction is reduced or eliminated, if the material is pure enough. Therefore, if the polyimide is formed from a ester based precursor the intermediate layer between the copper and the polymer acts mainly as a adhesion layer assuring good adhesion between the resulting copper film and the polymer. When a polymer is used in combination with aluminum conductors, the aluminum does not affect the dielectric properties of the polymer; but the aluminum conductors suffer from the previously described resistance-heating problem. To avoid this problem, the thickness of the aluminum is increased. Unfortunately, increasing the thickness of the aluminum increases the capacitance between the conductors. Further, Aluminum has a high coefficient of thermal expansion which can result in failures on the integrated circuit. For these and other reasons there is a need for the present invention.

### SUMMARY OF THE INVENTION

The present invention solves many of the problems listed above and others which will become known to those skilled in the art upon reading and understanding the present disclosure. The invention includes a connector which is formed by a method comprising several processes. An insulator is deposited over a planarized surface, and a trench is etched in the insulator. A barrier layer is deposited on the insulator, and a seed layer is deposited on the barrier layer. The barrier layer and the seed layer are removed from selected areas or unused areas of the insulator, leaving the seed area, and a conductor is deposited on the seed area. Integrated circuits may be formed using the structure of the present invention having improved interconnect conductivity with lower capacitance.

### BRIEF DESCRIPTION OF THE DRAWINGS

FIG. 1 is a cross-sectional view of one embodiment of a connector embedded in an integrated circuit structure.

FIG. 2A is a perspective view of a structure formed using a dual damascene process that is suitable for use in connection with the present invention.

FIG. 2B is a cross-sectional view of a connective structure used in connection with a structure formed using a dual damascene process.

FIG. 3 is a block diagram of a computer system suitable for use in connection with the present invention.

### DETAILED DESCRIPTION OF THE PREFERRED EMBODIMENTS

In the following detailed description of the preferred embodiments, reference is made to the accompanying drawings which form a part hereof, and in which is shown by way of illustration specific preferred embodiments in which the invention may be practiced. These embodiments are described in sufficient detail to enable those skilled in the art to practice the invention, and it is to be understood that other embodiments may be utilized and that logical, mechanical and electrical changes may be made without departing from the spirit and scope of the present invention. The following detailed description is, therefore, not to be taken in a limiting sense, and the scope of the present invention is defined only by the appended claims.

In general, the present invention includes a connector conductor which is formed by a method comprising several alternative processes. In one embodiment, an insulator is deposited over a planarized surface, and a trench is etched in the insulator. A barrier layer is deposited on the insulator, and a seed layer is deposited on the barrier layer. The barrier layer and the seed layer are removed from selected areas of the insulator, leaving the seed area, and a conductor is deposited on the seed area by a selective deposition process. Many different embodiments of the present invention are described below. For example, In one other embodiment, the barrier layer is deposited on the insulator by physical vapor-deposition.

In other embodiments, the trench is etched to a depth about equal to the depth of the insulator. The barrier layer deposited on the Polyimide formed from a ester based monomer layer is selected from the group consisting of titanium, zirconium, and hafnium. The conductor may be selected from the group consisting of gold, silver, and copper, which may be deposited on the seed area by electroless plating. In yet other embodiments, the insulator deposited over the planarized surface is a polymer, the seed layer is copper and the barrier layer is tantalum nitride, and a layer of tantalum nitride is deposited above the conductor.

In another embodiment the barrier layer is deposited on a oxide layer and is selected from the group consisting of titanium, zirconium and hafnium; the conductor is aluminum or aluminum copper and the seed layer is aluminum, aluminum copper or copper.

In another embodiment, an oxide layer is deposited over a planarized surface, and a trench having a top is etched on the oxide layer. A barrier layer of tantalum or tantalum nitride is deposited on the oxide layer. A layer of copper is deposited on the oxide layer. The barrier layer and the seed layer are removed from selected areas and unused areas of the oxide layer, leaving a seed area. A layer of copper is deposited on the seed area, and a layer of tantalum nitride is deposited above the copper layer.

In other embodiments, tantalum nitride is deposited to a depth of approximately one-hundred angstroms. The barrier layer of tantalum nitride is deposited by a non-anisotropic deposition technique. A connective structure may comprise an insulator deposited above a planarized surface. The insulator has a trench, and the trench has a trench surface. A barrier layer is above the trench surface. A seed layer is above the barrier layer, and a conductor is above the seed layer.

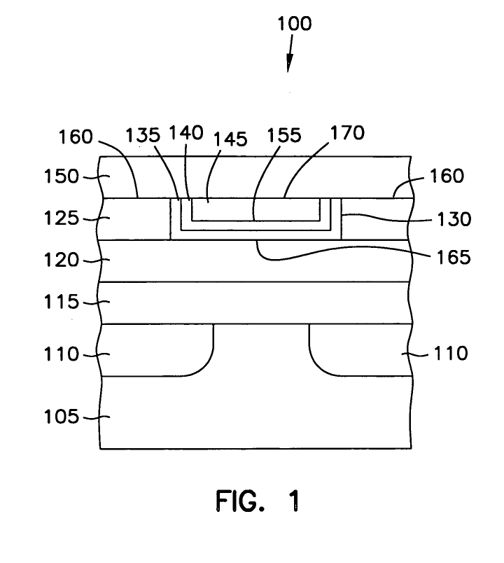

FIG. 1 is a cross-sectional view of one embodiment of a connector embedded in an integrated circuit structure. Structure 100 comprises substrate 105, device 110, insulating layer 115, diffusion barrier layer 120, insulating layer 125, trench 130, barrier layer 135, seed layer 140, conductor 145, and insulating layer 150.

Device 110 is formed on substrate 105. Insulating layer 115 is deposited on substrate 105. Insulating layer 115 is planarized, and diffusion barrier layer 120 is deposited on planarized insulating layer 115. Insulating layer 125 is deposited on diffusion barrier layer 120, and trench 130 is etched into insulating layer 125. Barrier layer 135 is deposited on insulating layer 125, and seed layer 140 is deposited on barrier layer 135. Seed layer 140 and barrier layer 135 are selectively removed from insulating layer 125, leaving seed area 155. Conductor 145 is deposited on seed area 155, and insulating layer 150 is deposited above insulating layer 125.

Substrate 105, in one embodiment, is silicon, however, the invention is not limited to a particular substrate material and the substrate material is not critical to the practice of the invention. Other substrate materials suitable for use in the present invention include germanium, gallium arsenide, and silicon-on-sapphire.

Device 110, in one embodiment, is an electronic device, such as a transistor, resistor, or capacitor, and is fabricated on substrate 105. The present invention is not limited to use in connecting any particular type of electronic device. Rather, the present invention is suitable for use in connecting a wide range of electronic devices. For example, in one embodiment, the cross-sectional area of connector conductor 145 can be increased and then used to connect high current switching transistors.

Insulating layer 115, in one embodiment, blocks undesired current flow from substrate 105 to layers above insulating layer 115. The material selected for insulating layer 115 is not critical to the practice of the present invention. In one embodiment, insulating layer 115 is silicon dioxide. After insulating layer 115 is deposited on substrate 105, the surface of insulating layer 115 is planarized. Chemical mechanical polishing or a similar process is suitable for planarizing the surface of insulating layer 115.

Diffusion barrier layer 120, in one embodiment, is deposited on insulating layer 115 and blocks impurities from subsequent processing from entering insulating layer 115 and substrate 105. In one embodiment, a layer of Si₃N₄ is deposited on insulating layer 115 to form diffusion barrier layer 120.

Insulating layer 125 is deposited on diffusion barrier layer 120. In one embodiment, insulating layer 125 is an oxide. In another embodiment, the oxide is silicon dioxide. In another embodiment, the oxide is a fluorinated silicon oxide. In another embodiment, insulating layer 125 is a polymer. In still another embodiment, the polymer is a foamed polymer. In still another embodiment, the polymer is a polyimide. The thickness of insulating layer 125, in one embodiment, is about equal to the thickness of connector conductor 145.

It is important to note that insulating layer 125 is deposited above a planarized surface, which in one embodiment is the planarized surface of insulating layer 115. Depositing insulating layer 125 above a planarized surface ensures that subsequent processes that remove seed layer 140 and barrier layer 135 from selected areas or unused areas 160 of the surface of insulating layer 125 are performed on a planar surface, which makes the removal process fast and efficient. It also results in fewer defects to other integrated circuit structures during the removal process, when compared with a removal process performed on a non-planar surface.

Connector 165 is fabricated by etching trench 130 into insulating layer 125, depositing barrier layer 135 on insulating layer 125, depositing seed layer 140 on insulating layer 125, removing seed layer 140 and barrier layer 135 from selected areas 160 of insulating layer 125, and leaving seed area 155 at the bottom and along the sides of trench 130.

Trench 130 is etched to a depth and width that provide the desired resistance in connector 165. Since the resistance of conductor 145 is inversely proportional to the cross-sectional area of conductor 145, the greater the depth and width of trench 130, the less the resistance of conductor 145, for a given conductor. However, it is preferable to decrease the resistance of conductor 145 by increasing the width of trench 130 as opposed to increasing the depth, since increasing the depth increases the capacitance between adjacent connectors, which limits the information transfer rate along conductor 145. Top 170 of trench 130 is in the same plane as the surface of insulating layer 125.

Barrier layer 135 is deposited on insulating layer 125 in order to block the flow of impurities, created during subsequent processing, into insulating layer 125. In one embodiment, barrier layer 135 is selected from the group consisting of titanium, zirconium, and hafnium. In another embodiment, the barrier layer is selected from the group consisting of zirconium and titanium. In still another embodiment, barrier layer 135 is tantalum nitride. In one embodiment, the thickness of the barrier layer is between about fifty and about one-thousand angstroms. In one embodiment, the tantalum nitride is deposited to a depth of approximately one-hundred angstroms. The barrier layer is deposited by sputtering, physical vapor deposition, or other vapor deposition technique. In one embodiment, a barrier layer 135 of tantalum nitride is deposited by a non-anisotropic deposition technique.

Seed layer 140 is deposited on barrier layer 135, in order to provide a site for depositing a metal to form a conducting integrated circuit connector. Seed layer 140 is formed from a conducting material. In one embodiment, seed layer 140 is selected from the group of conducting materials consisting of gold, silver, and copper. In another embodiment, seed layer 140 is an alloy of a metal selected from the group consisting of gold, silver, and copper. In still another embodiment, seed layer 140 is an aluminum-copper alloy. Seed layer 140 must be sufficiently thick to act as a seed layer for a selective deposition process. In one embodiment, a seed layer of copper is deposited to a depth of approximately five-hundred angstroms. In one embodiment, the seed layer is deposited by physical vapor deposition. In an alternate embodiment, the seed layer is deposited by chemical vapor-deposition.

Chemical mechanical polishing, in one embodiment, is used to remove barrier layer 135 and seed layer 140 from selected areas 160 of insulating layer 125. Seed layer 140 and barrier layer 135 are not removed from the seed area along the bottom and sides of trench 130. Since insulating layer 115 is planarized, only the surface of insulating layer 125, with the relatively thin barrier layer 135 and seed layer 140, are exposed to the chemical mechanical polishing process. A hard pad polish is preferred, in order to reduce the removal of seed layer 140 from trench 130. At the completion of the chemical mechanical polishing process, seed layer 140 remains on the bottom and sides of trench 130.

Conductor 145 is deposited on seed area 155, after barrier layer 135 and seed layer 140 are removed from selected areas 160 of insulating layer 125, leaving seed area 155. In one embodiment, conductor 145 is selected from the group consisting of gold, silver, and copper. In another embodiment, conductor 145 is an alloy of gold, silver, and copper. In still another embodiment, conductor 145 is an alloy of aluminum. Conductor 145, in one embodiment, is deposited by an electroless plating process. In one embodiment, conductor 145 is deposited to a depth sufficient to fill trench 130.

Insulating layer 150, in one embodiment, is deposited above insulating layer 125, after barrier layer 135 and seed layer 140 are deposited on insulating layer 125, and conductor 145 is deposited on seed layer 140. In one embodiment, insulating layer 150 is silicon dioxide. In an alternate embodiment, insulating layer 150 is tantalum nitride. In a preferred embodiment, insulating layer 150 is tantalum nitride, barrier layer 135 is tantalum nitride, seed layer 140 is copper, and conductor 145 is copper Device 110 can be connected to conductor 145 through conductive vias and other structures known in the art.

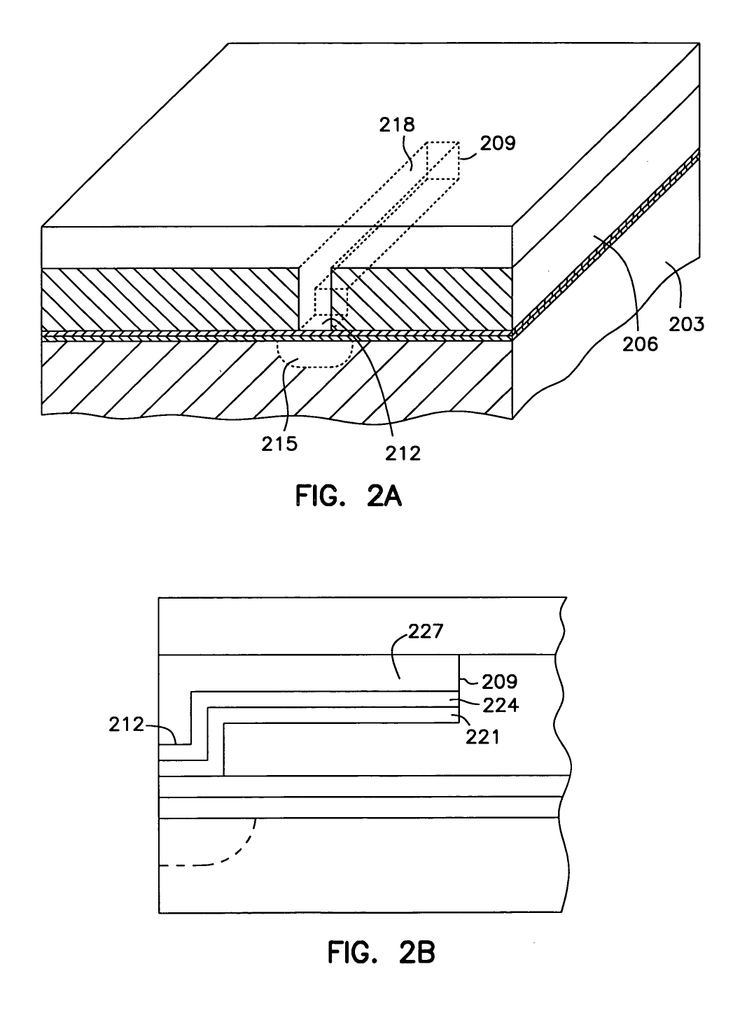

A specific use of the present invention is illustrated in FIG. 2A and FIG. 2B. FIG. 2A shows a dual damascene structure suitable for use in connection with the present invention. FIG. 2B shows the use of a dual damascene metallization process with a barrier layer of tantalum nitride and a copper conductor. However, the present invention is not meant to be limited to the use of a copper conductor and a tantalum nitride barrier layer. A variety of materials, such as aluminum, aluminum-copper, and gold can be used in connection with the present invention and the dual damascene process. In addition, a variety of devices, such as memory cells, capacitors, and transistors, can be interconnected using such a dual damascene process with a copper, gold, silver, aluminum or aluminum-copper material as an interconnect.

As illustrated in FIG. 2A, substrate 203 is conventionally processed using a dual damascene process up to the point where the first level of interconnection metal is to be formed. The conventional processing includes etching oxide 206 to form trench 209, forming a photoresist pattern to define contact site 212, and then etching oxide 206 to form contact site 212. The photoresist is removed to leave a finished damascene structure.

Also illustrated in FIG. 2A, contact site 212 is defined to device 215 of substrate 203. The damascene structure has two levels, a contact level at device 215 underlying a metallization level. At the metallization level, trench 209 is defined and extends over contact site 212 and defines the position and width of the metal line that is subsequently formed in trench 209 and contact site 212.

To form contact site 212 and trench 209, the structure illustrated in FIG. 2A is patterned using conventional photolithography and etching. Due to the nature of the dual damascene process, the depth of the etch is variable across the surface of the substrate, e.g., the etch depth is greater where contact site 212 is defined and less where only trench 209 is defined. Thus, two mask and etch steps can be utilized in a conventional photolithographic process to define the contact site 212 separately from the trench 209. Alternatively, a gray mask pattern can be utilized to define contact site 212 and trench 209 simultaneously in one photolithographic mask and etch step.

FIG. 2B is a cross-sectional view of trench 209 and contact site 212 of FIG. 2A. After trench 209 and contact site 212 are formed, a barrier layer of tantalum nitride 221 is deposited above the trench surface. Next, a seed layer of copper 224 is deposited above the barrier layer. Next, a layer of copper 227 is deposited above seed layer 224. Still referring to FIG. 2B, copper 218 is deposited and etched back in the contact site 212 and trench 209. Alternatively, gold, aluminum, silver, or an aluminum-copper composite can be deposited in trench 209 and contact site 212. A wide variety of suitable methods are available for depositing copper 218. Most techniques are physical techniques (e.g., sputtering and evaporating). The advantage of a dual damascene process is that only one copper 218 deposition step is needed to fill both contact site 212 and trench 209. Excess metal 218 deposited outside of the defined contact site 212 and trench 209 is etched back using any suitable method. For example, planarization (e.g., using at least one of a chemical or mechanical technique) is one suitable method. The sequence of steps described is then repeated, if necessary, depending on the number of conductive layers in the metallization level of the substrate.

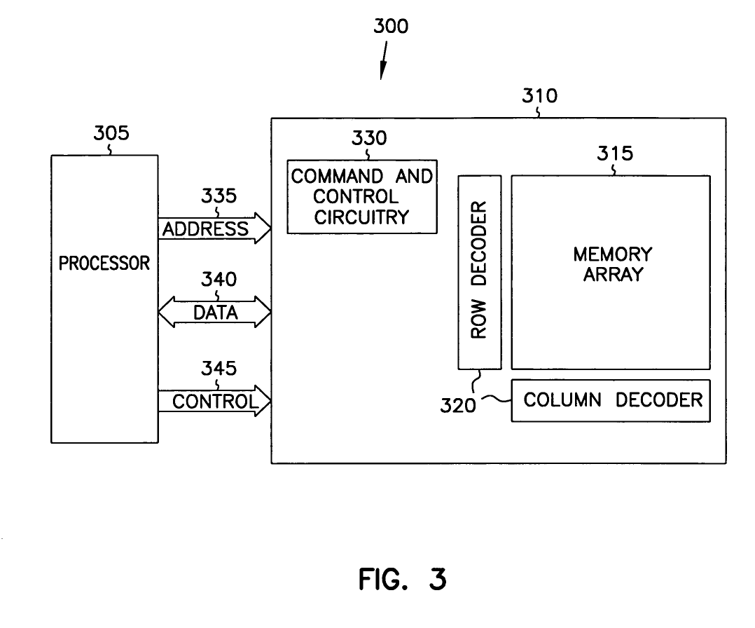

Referring to FIG. 3, a block diagram of a system level embodiment of the present invention is shown. System 300 comprises processor 305 and memory device 310, which includes conductive structures of one or more of the types described above in conjunction with FIG. 1, FIG. 2A, and FIG. 2B. Memory device 310 comprises memory array 315, address circuitry 320, and read circuitry 330, and is coupled to processor 305 by address bus 335, data bus 340, and control bus 345. Processor 305, through address bus 335, data bus 340, and control bus 345 communicates with memory device 310. In a read operation initiated by processor 305, address information, data information, and control information are provided to memory device 310 through busses 335, 340, and 345. This information is decoded by addressing circuitry 320, including a row decoder and a column decoder, and read circuitry 330. Successful completion of the read operation results in information from memory array 315 being communicated to processor 305 over data bus 340.

Embodiments of the present invention further include systems, such as electronic or computer systems. Examples follow, however, the present disclosure is not limited to these examples. A computer system includes a processor, a device coupled to the processor, and a connective structure coupled to the device, the connective structure includes, in an embodiment, an oxide layer above the planarized surface, the oxide layer having a trench, the trench having a trench surface, a barrier layer tantalum above the trench surface, and a gold layer above the barrier layer. In an embodiment, the connective structure includes a barrier layer having tantalum above the trench surface, a seed layer of silver above the barrier layer, and a silver layer above the barrier layer. In an embodiment, the barrier layer has a depth of between fifty angstroms and one-thousand angstroms. In an embodiment, the seed layer includes copper above the barrier layer. In an embodiment, a copper layer is above the seed layer. In an embodiment, the barrier layer has a depth of between fifty angstroms and one-thousand angstroms. In an embodiment, a copper layer is above the barrier layer. In an embodiment, a polymer layer is above a planarized surface, the polymer layer having a trench, the trench having a trench surface and a seed layer is selected from the group consisting of gold, silver, and copper above the barrier layer. In an embodiment, the barrier layer is selected from the group consisting of titanium, zirconium, and hafnium above the trench surface, a seed layer of gold above the barrier layer, and a gold layer above the seed layer. In an embodiment, the seed layer is of silver and above the barrier layer with a silver layer above the seed layer. In an embodiment, the seed layer is of copper above the barrier layer and a copper layer above the seed layer. In an embodiment, the seed layer is of aluminum-copper above the barrier layer. In an embodiment, an aluminum layer is above the seed layer. In an embodiment, the aluminum layer fills the trench. In an embodiment, a tantalum nitride layer is above the conductor layer. In an embodiment, the seed layer is approximately five-hundred angstroms of copper. In an embodiment, the barrier layer is between fifty angstroms and one-thousand angstroms. In an embodiment, the trench has a top and the seed layer is approximately five-hundred angstroms below the top of the trench. In an embodiment, the barrier layer has a depth of approximately five-hundred angstroms. In an embodiment, the oxide layer is a silicon dioxide layer. In an embodiment, the oxide layer is a fluorinated silicon oxide layer. In an embodiment, the barrier layer has a depth of approximately one-hundred angstroms. In an embodiment, the seed layer has a depth of approximately five-hundred angstroms. In an embodiment, the trench has a top and the copper is approximately five-hundred angstroms below the top of the trench. In an embodiment, the tantalum nitride above the copper is deposited to a depth of approximately five-hundred angstroms. In an embodiment, the oxide layer is a silicon dioxide layer. In an embodiment, the oxide layer is a fluorinated silicon oxide layer.

### CONCLUSION

Several embodiments of a method for fabricating conducting structures in an integrated circuit have been described. These embodiments exhibit reduced resistance induced heating in the conducting structures and low capacitive coupling between conductors. Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present invention. Therefore, it is manifestly intended that this invention be limited only by the claims and the equivalents thereof.

1. A connective structure comprising:
an insulator above a planarized surface, the insulator having a trench, the trench having a trench surface;
a barrier layer above the trench surface;
a seed layer above the barrier layer; and
a conductor above the seed layer.

2. The connective structure of claim 1, wherein the insulator has a depth, the trench has a depth and the depth of the trench is about equal to the depth of the insulator.

3. A connective structure comprising:
an oxide layer above the planarized surface, the oxide layer having a trench, the trench having a trench surface;
a barrier layer above the trench surface;
a seed layer above the barrier layer; and
a conductor above the seed layer.

4. The connective structure of claim 3, wherein the oxide layer is a silicon dioxide layer.

5. The connective structure of claim 3, wherein the oxide layer is a fluorinated silicon oxide layer.

6. A connective structure comprising:
a polymer layer above the planarized surface, the polymer layer having a trench, the trench having a trench surface;
a barrier layer above the trench surface;
a seed layer above the barrier layer; and
a conductor above the seed layer.

7. The connective structure of claim 6, wherein the polymer layer is a polyimide layer.

8. The connective structure of claim 6, wherein the polymer layer is a foamed polymer layer.

9. A connective structure comprising:
an oxide layer above the planarized surface, the oxide layer having a trench, the trench having a trench surface;
a barrier layer tantalum above the trench surface;
a seed layer selected from the group consisting of gold, silver, and copper above the barrier layer; and
a conductor above the seed layer.

10. The connective structure of claim 9, wherein the barrier layer has a depth of between fifty angstroms and one-thousand angstroms.

11. A connective structure comprising:
an oxide layer above the planarized surface, the oxide layer having a trench, the trench having a trench surface;
a barrier layer tantalum above the trench surface;
a seed layer of gold above the barrier layer; and
a gold layer above the seed layer.

12. The connective structure of claim 11, wherein the barrier layer has a depth of between fifty angstroms and one-thousand angstroms.

13. A connective structure comprising:
an oxide layer above the planarized surface, the oxide layer having a trench, the trench having a trench surface;
a barrier layer tantalum above the trench surface; and
a gold layer above the barrier layer.

14. A connective structure comprising:
an oxide layer above the planarized surface, the oxide layer having a trench, the trench having a trench surface;
a barrier layer tantalum above the trench surface;
a seed layer of silver above the barrier layer; and
a silver layer above the barrier layer.

15. The connective structure of claim 14, wherein the barrier layer has a depth of between fifty angstroms and one-thousand angstroms.

16. A connective structure comprising:
an oxide layer above the planarized surface, the oxide layer having a trench, the trench having a trench surface;
a barrier layer tantalum above the trench surface; and
a silver layer above the barrier layer.

17. A connective structure comprising:
an oxide layer above the planarized surface, the oxide layer having a trench, the trench having a trench surface;
a barrier layer tantalum above the trench surface;
a seed layer of copper above the barrier layer; and
a copper layer above the seed layer.

18. The connective structure of claim 17, wherein the barrier layer has a depth of between fifty angstroms and one-thousand angstroms.

19. A connective structure comprising:
an oxide layer above the planarized surface, the oxide layer having a trench, the trench having a trench surface;
a barrier layer tantalum above the trench surface; and
a copper layer above the barrier layer.

20. A connective structure comprising:
a polymer layer above a planarized surface, the polymer layer having a trench, the trench having a trench surface;
a barrier layer selected from the group consisting of titanium, zirconium, and hafnium above the trench surface;
a seed layer selected from the group consisting of gold, silver, and copper above the barrier layer; and
a conductor layer above the seed layer.

21. The connective structure of claim 20, wherein the barrier layer has a depth of between fifty angstroms and one-thousand angstroms.

22. A connective structure comprising:
a polymer layer above a planarized surface, the polymer layer having a trench, the trench having a trench surface;
a barrier layer selected from the group consisting of titanium, zirconium, and hafnium above the trench surface;
a seed layer of gold above the barrier layer; and
a gold layer above the seed layer.

23. The connective structure of claim 22, wherein the barrier layer has a depth of between fifty and one-thousand angstroms.

24. A connective structure comprising:
a polymer layer above a planarized surface, the polymer layer having a trench, the trench having a trench surface;
a barrier layer selected from the group consisting of titanium, zirconium, and hafnium above the trench surface; and
a gold layer above the barrier layer.

25. A connective structure comprising:
a polymer layer above a planarized surface, the polymer layer having a trench, the trench having a trench surface;
a barrier layer selected from the group consisting of titanium, zirconium, and hafnium above the trench surface;
a seed layer of silver above the barrier layer; and
a silver layer above the seed layer.

26. The connective structure of claim 25, wherein the barrier layer has a depth of between fifty angstroms and one-thousand angstroms.

27. A connective structure comprising:
a polymer layer above a planarized surface, the polymer layer having a trench, the trench having a trench surface;
a barrier layer selected from the group consisting of titanium, zirconium, and hafnium above the trench surface; and
a silver layer above the barrier layer.

28. A connective structure comprising:
a polymer layer above a planarized surface, the polymer layer having a trench, the trench having a trench surface;
a barrier layer selected from the group consisting of titanium, zirconium, and hafnium above the trench surface;
a seed layer of copper above the barrier layer; and
a copper layer above the seed layer.

29. The connective structure of claim 28, wherein the barrier layer has a depth of between fifty angstroms and one-thousand angstroms.

30. A connective structure comprising:
a polymer layer above a planarized surface, the polymer layer having a trench, the trench having a trench surface;
a barrier layer selected from the group consisting of titanium, zirconium, and hafnium above the trench surface;
a seed layer of copper above the barrier layer; and
a copper layer above the seed layer.

31. A connective structure comprising:
an oxide layer above a planarized surface, the oxide layer having a trench, the trench having a trench surface;
a barrier layer selected from the group consisting of zirconium and titanium above the trench surface;
a seed layer of aluminum-copper above the barrier layer; and
a conductor above the seed layer.

32. The connective structure of claim 31, wherein the barrier layer has a depth of between fifty angstroms and one-thousand angstroms.

33. A connective structure comprising:
an oxide layer above a planarized surface, the oxide layer having a trench, the trench having a trench surface;
a barrier layer selected of zirconium above the trench surface;
a seed layer of aluminum-copper above the barrier layer; and
an aluminum layer above the seed layer.

34. The connective structure of claim 33, wherein the barrier layer has a depth of between fifty and one-thousand angstroms.

35. The connective structure of claim 33, wherein the aluminum layer fills the trench.

36. A connective structure comprising:
an oxide layer above a planarized surface, the oxide layer having a trench, the trench having a trench surface;
a barrier layer of titanium above the trench surface;
a seed layer of aluminum-copper above the barrier layer; and
an aluminum layer above the seed layer.

37. The connective structure of claim 36, wherein the barrier layer has a depth o between fifty angstroms and one-thousand angstroms.

38. The connective structure of claim 36, where the aluminum layer fills the trench.

39. A connective structure comprising:
an oxide layer above a planarized surface, the oxide layer having a trench, the trench having a trench surface;
a barrier layer of tantalum nitride above the trench surface;
a seed layer of copper above the barrier layer;
an conductor layer above the seed layer; and
a tantalum nitride layer above the conductor layer.

40. The connective structure of claim 39, wherein the depth of the barrier layer is approximately one-hundred angstroms.

41. The connective structure of claim 39, wherein the seed layer is approximately five-hundred angstroms of copper.

42. The connective structure of claim 39, wherein the barrier layer is between fifty angstroms and one-thousand angstroms.

43. The connective structure of claim 39, wherein the trench has a top and the seed layer is approximately five-hundred angstroms below the top of the trench.

44. The connective structure of claim 39, wherein the barrier layer has a depth of approximately five-hundred angstroms.

45. The connective structure of claim 39, wherein the oxide layer is a silicon dioxide layer.

46. The connective structure of claim 39, wherein the oxide layer is a fluorinated silicon oxide layer.

47. A connective structure comprising:
an oxide layer above a planarized surface, the oxide layer having a trench, the trench having a trench surface;
a barrier layer of tantalum nitride above the trench surface;
a seed layer of copper above the barrier layer;
a copper layer above the seed layer; and
a tantalum nitride layer above the copper layer.

48. The connective structure of claim 47, wherein the barrier layer has a depth of approximately one-hundred angstroms.

49. The connective structure of claim 47, wherein the seed layer has a depth of approximately five-hundred angstroms.

50. The connective structure of claim 47, wherein the barrier layer has a depth of between approximately fifty angstroms and one-thousand angstroms.

51. The connective structure of claim 47, wherein the trench has a top and the copper is approximately five-hundred angstroms below the top of the trench.

52. The connective structure of claim 47, wherein the tantalum nitride above the copper is deposited to a depth of approximately five-hundred angstroms.

53. The connective structure of claim 47, wherein the oxide layer is a silicon dioxide layer.

54. The connective structure of claim 47, wherein the oxide layer is a fluorinated silicon oxide layer.

55. A computer system comprising:
a processor;
a device coupled to the processor; and
a connective structure coupled to the device, the connective structure comprising:
an insulator above a planarized surface, the insulator having a trench, the trench having a trench surface;
a barrier layer above the trench surface;
a seed layer above the barrier layer; and
a conductor above the seed layer.

56. The computer system of claim 55, wherein the insulator has a depth, the trench has a depth and the depth of the trench is about equal to the depth of the insulator.

57. The computer system of claim 55, wherein the insulator layer includes an oxide layer.

58. The computer system of claim 57, wherein the oxide layer includes a silicon dioxide layer.

59. The computer system of claim 57, wherein the oxide layer is a fluorinated silicon oxide layer.

60. The computer system of claim 55, wherein the insulator layer includes a polymer.

61. The computer system of claim 60, wherein the polymer is a polyimide layer.

62. The computer system of claim 60, wherein the polymer is a foamed polymer layer.

63. The computer system of claim 55, wherein the barrier layer includes tantalum and wherein the seed layer is selected from the group consisting of gold, silver, and copper above the barrier layer.

64. The computer system of claim 63, wherein the barrier layer has a depth of between fifty angstroms and one-thousand angstroms.
